(19) United States
(12) Patent Application Publication
(10) Pub. No.: US 2013/0037085 A1
(43) Pub. Date: Feb. 14, 2013

(54) SOLAR CELL MODULE

(71) Applicants: Jürgen H. Werner, Stuttgart (DE); Liv Prönneke, Stuttgart (DE)

(72) Inventors: Jürgen H. Werner, Stuttgart (DE); Liv Prönneke, Stuttgart (DE)

(21) Appl. No.: 13/520,105

(22) PCT Filed: Dec. 20, 2010
(86) PCT No.: PCT/EP2010/007781

§ 371 Date: Oct. 2, 2012

(30) Foreign Application Priority Data
Jan. 5, 2010 (DE) 10 2010 004 439.3

(51) Int. Cl. H01L 31/052; H01L 31/18

(52) U.S. Cl. 136/249; 438/69; 257/E31.127

(57) ABSTRACT

The invention relates to a solar cell module which comprises a base having photovoltaically active zones and photovoltaically inactive zones, at least one diffractive element being arranged above at least one photovoltaically inactive zone of the base.

### BACKGROUND OF THE INVENTION

In conventional solar cells, the front contacts provided are made of metal. Solar rays that fall on these front contacts are reflected and leave the respective system without being able to impinge on individual solar cells. These photons are thus lost for the purpose of generating photovoltaic power. Photons that fall on “contact fingers” are also lost. Moreover, photons that fall on surfaces that are neither optically nor electrically active, i.e. areas between solar cells or towards the edge of the module, are also lost. In “thin-film modules”, there are also losses due to shadowing effects. When solar cells are serially connected, this results in surface losses of approximately 5-10% of the overall area. Theoretically, these losses could be reduced to 2%. Moreover, in thin-film modules, between one and two of the outermost solar cells are not connected, which means they are not electrically active.

Research is already being done to optically improve contact bands. In this connection, reference is made to the document US 2007/0125415 A1, which proposes structuring the contact bands in a wedge shape. This structure is already being implemented in the industry. Furthermore, the Sunage company is engaged in a project to apply a Lambertian radiator coating to the areas between the solar cells.

Usually the structures of the contact bands reflect incident photons in a highly angle-dependent manner. They are usually optimized for vertical incident light. Under real conditions, however, it is very rare that direct vertical light actually occurs in systems that do not move to track the light source. The Lambertian radiator used by Sunage does not have this disadvantage since scattering is the same for every angle of incoming light. However, the project is limited to the areas between the solar cells and does not deal with corresponding cell connectors and contact fingers on the respective solar cells.

### SUMMARY OF THE INVENTION

The invention relates to a solar cell module consisting of a base with photovoltaically active and photovoltaically inactive areas in which at least one scattering element with or without electromagnetic shift is arranged above at least one photovoltaically inactive area of the base or a cell level of the solar cell module.

A scattering element with electromagnetic shift means a scattering element that, in addition to its property of scattering incoming light rays, is also able to absorb incident light rays and re-emit them with changed wavelengths, i.e. effecting an electromagnetic shift of the incident light rays. In the following description, the terms light rays, solar rays, photons and electromagnetic waves are used as synonyms.

It is conceivable that in addition to the at least one scattering element, an additional scattering element is arranged above the at least one photovoltaically inactive area.

In this case, for example, there can be a scattering element without electromagnetic shift arranged above the at least one photovoltaically inactive area of the base in addition to at least one scattering element with electromagnetic shift, the at least one scattering element with electromagnetic shift being generally arranged above the scattering element without electromagnetic shift. The at least one scattering element with electromagnetic shift is usually constituted as a fluorescent pigment. The at least one scattering element without electromagnetic shift can be constituted as a Lambertian scatterer.

Accordingly, in the solar cell module, at least one Lambertian scatterer can be placed as a scattering element without electromagnetic shift above the at least one photovoltaically inactive area of the base, above which scatterer in turn a fluorescent pigment is arranged as a scattering element with electromagnetic shift.

The base of a solar cell module that encompasses the photovoltaically inactive and active areas together with the various components of said areas is usually embedded in a transparent material. Said scattering element(s) is/are placed between a surface of the transparent material that separates the solar cell module from the environment and the at least one photovoltaically inactive area of the base. In the event that both a scattering element with and a scattering element without electromagnetic shift are present, the scattering element with electromagnetic shift, for example, is located between the surface of the transparent material and the at least one scattering element without electromagnetic shift. In this case, the at least one scattering element without electromagnetic shift is located between the scattering element with electromagnetic shift and the at least one photovoltaically inactive area of the base.

In a possible configuration of the solar cell module, the at least one scattering element without electromagnetic shift, for example a Lambertian scatterer, with a fluorescent pigment applied to it, as the at least one scattering element with electromagnetic shift, is placed on at least one photovoltaically inactive area of the base.

In the solar cell module, the at least one photovoltaically inactive area can encompass at least one area that is at least optically and/or electrically inactive. Thus, within the framework of the invention, photovoltaically active areas are those areas in which direct conversion of energy from electromagnetic radiation in the optical area and thus [the conversion] of light into electrical energy takes place. The photovoltaically inactive areas usually comprise components that hinder or prevent photovoltaic conversion of energy. The photovoltaically inactive areas of a solar cell module usually comprise all components of a solar cell module, including electronic components, that are not designed as solar cells or photovoltaic cells. Furthermore, the photovoltaically inactive areas also comprise components that are optically and/or electrically inactive, as a result, for instance, of the solar cell module being designed in such a manner. Therefore, the photovoltaically inactive areas may also include solar cells that, for example, are located at the periphery of a solar cell module and are at least partially optically inactive, and thus photovoltaically inactive due to shadowing effects. Each of said components therefore defines a photovoltaically inactive area.

A component of a photovoltaically inactive area or a component that defines the photovoltaically inactive area can, for instance, be a contact finger element arranged on a corresponding solar cell, [or it can be] a cell connector element, a space between solar cells, a border area located at the periphery of a solar cell module, or a solar cell that is at least optically inactive, and therefore photovoltaically inactive and which merely conducts power away. A photovoltaically inactive solar cell can become shaded by a frame of the solar cell module, for example. Furthermore, solar cells that are not connected can also be referred to as photovoltaically inactive areas.

Pursuant to the invention, it is now conceivable, for example, that either merely one scattering element with electromagnetic shift or merely one scattering element without electromagnetic shift, or a combination of at least one scattering element with, as well as at least one scattering element without, electromagnetic shift are provided or arranged on individual or on all of said photovoltaically inactive areas of a solar cell module.

Usually the fluorescent pigment that functions as the scattering element with electromagnetic shift is designed so as to shift a spectrum of incoming electromagnetic radiation. This can mean that the fluorescent pigment is designed so as to absorb photons and to emit photons with, for example, a higher wavelength and to thereby effect a spectral shift of the electromagnetic radiation toward waves with a higher wavelength. Depending on the wavelength at which the solar cells can obtain the highest yield of electrical energy, the wavelength of the radiation can be increased or decreased by the scattering element with electromagnetic shift realized in the form of fluorescent pigment.

Furthermore, it is usually provided that at least one component of the base of the solar cell module defining a photovoltaically inactive area and the at least one scattering element arranged above the component are suitably embedded in at least one optically transparent material. However, in this connection, for example, the at least one scattering element with electromagnetic shift can be alternatively or supplementarily arranged also on the upper side or underside of a transparent material.

Moreover, it may be provided that the solar cell module comprises a first transparent material consisting of plastic, in which the at least one component of the base is embedded, and a second transparent material consisting of glass, which is arranged or installed on the first transparent material. The at least one scattering element can be placed in the area of at least one of the transparent materials, for example, above, within, or under the first and/or second transparent material(s), for example, on the border between the two transparent materials. The first transparent material can, for example, be made of EVA foil, i.e. ethylene-vinyl acetate foil. The second transparent material can also be referred to as module glass. This means that the invention can also be used for flexible solar cell modules that are welded into plastic, for example.

When energy from electromagnetic waves is converted into electrical energy using an embodiment of a solar cell module, as described pursuant to the invention, electromagnetic waves that impinge on at least one photovoltaically inactive area of the solar module can be reflected using a scattering element without electromagnetic shift, such as a Lambertian scatterer, and their spectrum can be shifted by the at least one scattering element with electromagnetic shift—typically the fluorescent pigment—that is arranged above the scattering element without electromagnetic shift and that is typically applied onto the scattering element without electromagnetic shift. In this way the reflected and spectrally-shifted electromagnetic waves can be reflected at an inner side of the surface of the optically transparent material of the solar cell module toward areas with higher quantum efficiency.

Furthermore, the present invention comprises a method to produce a solar cell module.

In the method to produce a solar cell module, a base with photovoltaically active areas and photovoltaically inactive areas is supplied for the solar cell module. In this connection, at least one scattering element with or without electromagnetic shift is placed above the at least one photovoltaically inactive area of the base, where the scattering element with electromagnetic shift can be a fluorescent pigment.

Moreover, it may be provided that at least one additional scattering element is arranged above the at least one photovoltaically inactive area of the base. In this connection, it is conceivable to arrange an additional scattering element with electromagnetic shift in the form of a fluorescent pigment above a scattering element without electromagnetic shift.

For example, the at least one scattering element without electromagnetic shift is arranged on the at least one photovoltaically inactive area. Then, for example, the at least one scattering element with electromagnetic shift is applied onto the at least one scattering element without electromagnetic shift.

Components of the base can be embedded during manufacturing within or at an interface of at least one optically transparent material.

In addition to a scattering that is effected, independent of the angle of incidence, by a scattering element without electromagnetic shift, the application onto the scattering element without electromagnetic shift of fluorescent pigments acting as scattering elements with electromagnetic shift can shift the spectrum of incident radiation to a spectrum that is more beneficial for the solar cell. When an infrared or blue fluorescent pigment is used, it is additionally possible to modify the appearance or design of the solar cell module such that the surface of the solar cell module looks more uniform than is the case for the previously used silver-coloured contact bands or contact band elements and contact fingers arranged adjacent to, on and/or between solar cells as photovoltaically inactive components.

In a possible embodiment of the invention, it is among other things provided that at least one fluorescent pigment is applied, as the at least one scattering element with electromagnetic shift, to all areas of the module or areas of the base of the solar cell module that are at least optically inactive. Furthermore, it is conceivable to arrange and apply a scattering element without electromagnetic shift between the base and the at least one scattering element with electromagnetic shift.

It is also conceivable to provide only one scattering element without electromagnetic shift on the respective photovoltaically inactive components of the base of the solar cell module. The photovoltaically inactive components of the base of the solar cell module include contact finger elements and contact bands arranged on individual solar cells, and also spaces between solar cells. It may be advantageous in each case to provide at least one scattering element with or without electromagnetic shift or a combination of one scattering element with and one scattering element without electromagnetic shift on all of the photovoltaically inactive components.

The at least one scattering element with electromagnetic shift, e.g. the fluorescent pigment, shifts the incident light into a spectrum that is more beneficial for the solar cells of the solar cell module. In addition, the light is randomly radiated in all directions, similar to [what happens when light falls on] the scattering element without electromagnetic shift. The fluorescent pigment without electromagnetic shift can also be applied or arranged between the solar cells, however in one possible variant, not in or on the level of the solar cells, but rather on the underside of the module glass. This means that not only the rays scattered upward are directed by way of total reflection onto the solar cells, but also that rays radiating downward can be used by the solar cells.

In a potential embodiment, the invention can be used to activate the at least optically inactive areas, typically for thin-film modules, not only between the solar cells in a solar cell module, but also on the solar cells. Moreover, in addition to scattering, a spectral shift of the incident light may be provided that emits the photons to where the solar cells possess higher quantum efficiency.

Assuming that a monocrystalline silicon solar cell has a total area of 240.48 cm² and the contact bands located on it occupy 9.6 cm², the short circuit current density JSC=1.7 mA/cm² calculated from the quantum efficiency measurement results in an efficiency of 14.64% for a conventional contact band containing silver.

The invention can increase the efficiency of solar cell modules with crystalline and amorphous solar cells by using scattering and spectrum-shifting fluorescent pigments and therefore by using scattering elements with electromagnetic shift on photovoltaically inactive and therefore at least optically and/or electrically inactive areas of the base. The invention also makes it possible to photovoltaically activate at least optically and/or electrically inactive areas or surfaces in thin-film modules.

Additional advantages and embodiments of the invention are evident from the description and the attached drawings.

It is understood that the features referred to above and those yet to be explained below can be used not only in the respectively given combination, but also in other combinations or by themselves, without departing from the scope of the present invention.

### SHORT DESCRIPTION OF THE DRAWINGS

FIG. 1 is a diagrammatic top view of a first prior-art embodiment of a solar cell in a solar cell module.

FIG. 2 is a diagrammatic top view of a second prior-art embodiment of a solar cell module.

FIG. 3 is a diagrammatic side view of examples of components of solar cell modules.

FIG. 4 is a diagramatic side view of additional examples of components of solar cell modules.

FIG. 5 is a graph showing the quantum efficiency of various solar cell modules.

### EMBODIMENTS OF THE INVENTION

The invention is illustrated diagrammatically in the drawings using embodiments and is described in detail below, with reference being made to the drawings.

The figures are described consistently and comprehensively; the same reference numbers refer to the same components.

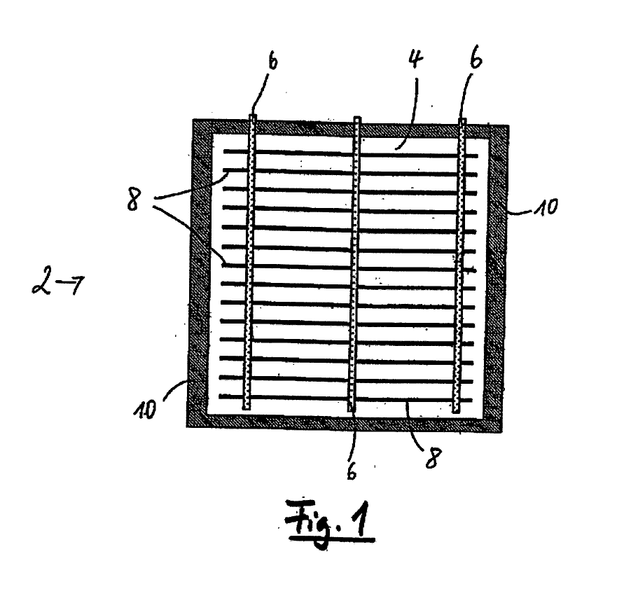

FIG. 1 is a diagrammatic top view of a section of a prior-art crystalline silicon solar cell module 2 with a base on which a number of solar cells 4 are arranged, with a solar cell 4 being illustrated here. In addition, the base comprises so-called cell connection elements 6, shown here as dotted lines, and contact finger elements 8 arranged on the respective solar cells 4. The base comprises a blank module surface 10 surrounding each of the solar cells 4 which surface serves, among other things, as a border to an adjacent solar cell or to a frame of the solar cell module 2.

The latter components, i.e. the cell connection elements 6, the contact finger elements 8 and the bare module surface 10, which is shown here in cross-hatch, are photovoltaically inactive in contrast to the solar cell 4, which is photovoltaically active. Accordingly, the cell connection elements 6, the contact finger elements 8 and the bare module surface 10 associated with the solar cell module 2 are, among other things, also at least optically inactive. The cell connection elements 6 of the solar cells 4 in the solar cell module 2 consist of metal. Solar rays that fall on these cell connection elements 6, which are designed as contacts, are reflected and leave the solar cell module 2 without being able to strike the solar cells 4. These photons are therefore lost for the purposes of generating photovoltaic power. Likewise, photons that impinge on the contact finger elements 8 are also lost. There are additional photovoltaically unused areas between the solar cells 4 and in the area of the frame of solar cell module 2 since photons that impinge on these areas are also lost for the purposes of generating power because they cannot strike solar cells 4.

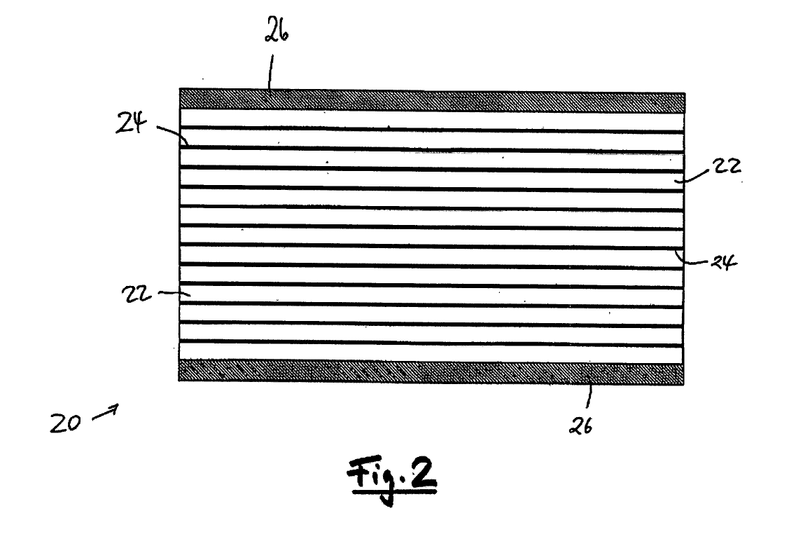

FIG. 2 is a diagrammatic top-view of a solar cell module 20 designed as a thin-film module with photovoltaically active areas comprising connected solar cells 22. The photovoltaically inactive areas of this solar cell module 20 here include cell connection elements 24, which serve to serially connect the solar cells 22, and outer solar cells 26, shown here in cross hatch, that here are merely provided in order to conduct power away but which are at least optically and therefore also photovoltaically inactive. In thin-film modules, there are also losses due to shadowing, with the area losses due to the serial connection amounting to between approximately 5-10% of the total area. Theoretically, these losses could be reduced to 2%. On the other hand, in thin-film modules, one to two of the outer solar cells 26 are not connected and are therefore not electrically or photovoltaically active since the power collected is conducted away by means of the outer solar cells 26.

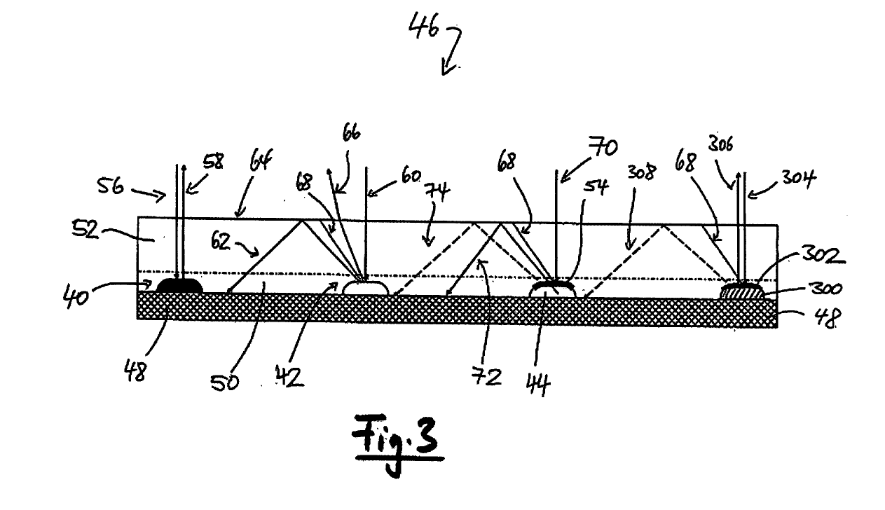

FIG. 3 is a schematic illustration of an arrangement with multiple examples for the design of cell connection elements 40, 42, 44, 300 that are designed as components of a solar cell module 46 and, together with solar cells 48, form part of a base of the solar cell module 46. The cell connection elements 40, 42, 44, 300 and the solar cells 48 are embedded in an ethylene-vinyl acetate foil, which constitutes a first transparent material 50. Module glass, constituting a second transparent material 52, is placed on this foil. A first cell connection element 40 (black) known from the prior art has a conventional, reflecting, e.g. metallic surface. A scattering element without electromagnetic shift, such as a Lambertian scatterer, is placed on the surface of the second cell connection element 42 (white).

A scattering element without electromagnetic shift a, for example, in the form of a Lambertian scatterer, is also placed on the surface of an additional cell connection element 44 (white). In addition, a scattering element with electromagnetic shift, e.g. a fluorescent pigment 54, is applied to the scattering element without electromagnetic shift. Only a scattering element with electromagnetic shift, e.g. a fluorescent pigment 302, is applied on an additional cell connection element 300 (cross-hatched), i.e. there is no additional scattering element provided in addition to the scattering element with electromagnetic shift.

FIG. 3 shows that a ray 56 falling on a first cell connection element 40, which is designed as a conventional front contact, exits the solar cell module 46 as a perpendicularly reflected ray 58.

A ray 60 falling on a second cell connection element 42 provided with a scattering element without electromagnetic shift will be scattered in the half-space located above. In the case of a Lambertian scatterer, this occurs equally in all directions. Rays 62 that hit the surface 64 of the module glass at an angle greater than or equal to the angle of total reflection land on solar cell 48. Rays 66 within a loss cone 68 of the total reflection will be transmitted. A ray 304 falling on the cell connection element 300 will be reflected as a ray 308 that has been spectrally changed or shifted.

The fluorescent pigment 54, 302, being a scattering element with electromagnetic shift, emits absorbed photons with, for example, a higher wavelength that is better suited to the spectral behavior of the solar cell module 46. This can mean that the wavelength is shifted into a region in which the solar cell module 46 will achieve a better efficiency. Rays not absorbed by the fluorescent pigment acting as a scattering element with electromagnetic shift will be scattered in accordance with the scattering characteristics of the fluorescent pigment itself or of the scattering element located underneath it (rays 72, 306). If there is no material designated specifically as a scattering element under the fluorescent pigment, as in the case of cell connection element 300, non-absorbed photons will be scattered by this material in accordance with its reflective properties.

Accordingly, the additionally applied fluorescent pigment 54, 302 shifts incident light or incident rays 70, 304 as reflected rays 74, 308 into a region of the spectrum where the solar cells 48 can achieve higher energy efficiency. The scattering element applied to the third cell connection element 44 scatters the non-absorbed rays 72 into the half-space located above it. Rays 304 falling perpendicularly on the cell connection element 300 without being absorbed by the fluorescent pigment 302 exit the solar cell module 46 as perpendicularly reflected rays 306.

The fluorescent pigment 54, 302, being a scattering element with electromagnetic shift, emits absorbed photons with, for example, a higher wavelength, at which the solar cells 48 exhibit better efficiency. In the case of the cell connection element 44, rays not absorbed by the fluorescent pigment 54, 302 are scattered by the scattering element installed beneath it or in the case of the cell connection element 300, by the material of which the cell connection element 300 consists, in accordance with its reflective properties.

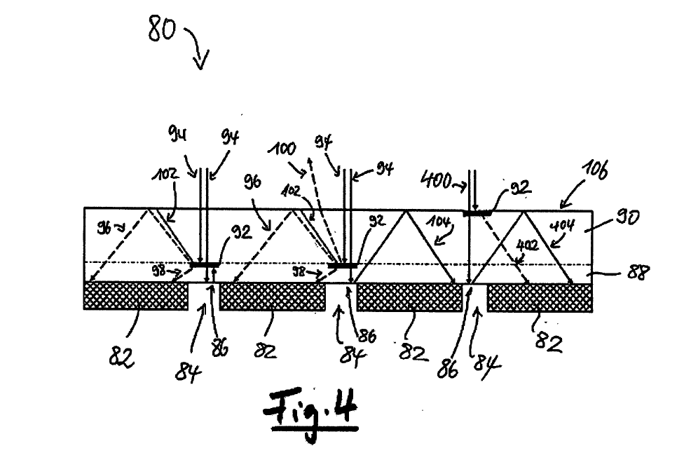

FIG. 4 is a diagrammatic side-view of another example of a solar cell module 80. It comprises a base with solar cells 82, which are separated from one another by spaces 84, which are photovoltaically inactive areas. Scattering elements 86 without electromagnetic shift are placed and thus arranged on the spaces 84. The solar cell module 80 comprises a first transparent material 88, being a foil made of ethylene-vinyl acetate, in which the solar cells 82 are embedded. Another transparent material 90, being module glass, is located on the foil. Above the first two spaces 84 and the scattering elements 86 without electromagnetic shift, a fluorescent pigment 92 is embedded under the module glass, within the foil, at a transition [area] to the foil. The fluorescent pigment 92 is applied to a surface 106 of the second transparent material 90, which is in the form of module glass, above the third space 84 and the scattering element without electromagnetic shift.

The principle of scattering provided within the scope of the invention can be applied not only to cell connection elements, but also to the various contact finger elements and areas between the solar cells 82 in the solar cell module 80. At that location there is no spectral shifting of the wavelength at the level of the solar cells 82, but rather this occurs by way of the scattering elements with electromagnetic shift 92 arranged on the underside or the upper side of the module glass. From a ray 94 entering the solar cell module 80, not only are the upward-scattered rays 96 directed through total reflection onto the solar cells 82, but also rays 98 or photons that pass through the fluorescent pigment 92, and thus through the scattering element with electromagnetic shift, are used by the solar cells 82. Rays 100 that fall within the loss cone 102 remain unused. Rays 104 totally reflected at the surface 106 and not absorbed by the scattering element with electromagnetic shift, i.e. the fluorescent pigment 92, can be scattered in such a way by the scattering element 86 placed on the level of the cell that they strike solar cell 82.

Due to the spectral shift, the additional application of the fluorescent pigment 92 makes the quantum efficiency higher than it would be if only the various scattering elements 86 were used.

Rays 94 falling on the fluorescent pigments 92, being scattering elements with electromagnetic shift, under the module glass will be scattered in equally distributed fashion in the upper half-space, rays 96 that strike the surface 106 of the module glass at an angle greater than or equal to that of the total reflection will reach solar cells 82. Rays 100 within the total reflection loss cone 102 will be transmitted. Rays 98 scattered downwards will also contact a solar cell 82 if they are scattered at a suitable angle. Rays 94 that are not absorbed by fluorescent pigments 92 will be scattered by materials applied on the cell level or base, in this case, the Lambertian scatterers 86, being scattering elements without electromagnetic shift, in accordance with the reflective properties of the materials.

The fluorescent pigment 92, being a scattering element with electromagnetic shift, is arranged above the third space 84 on or in the module glass, and the Lambertian scatterer 86, being a scattering element without electromagnetic shift, is arranged on the level of the cells. Rays 400 entering the solar cell module 80 will land as scattered rays 402 on a solar cell 82 if they are scattered at the correct angle by the scattering element with electromagnetic shift, i.e. the fluorescent pigment 92. Rays 404 that are not absorbed by the fluorescent pigment 92 are scattered by the scattering element 86 that is applied on the cell level in accordance with the reflective properties of said element 86.

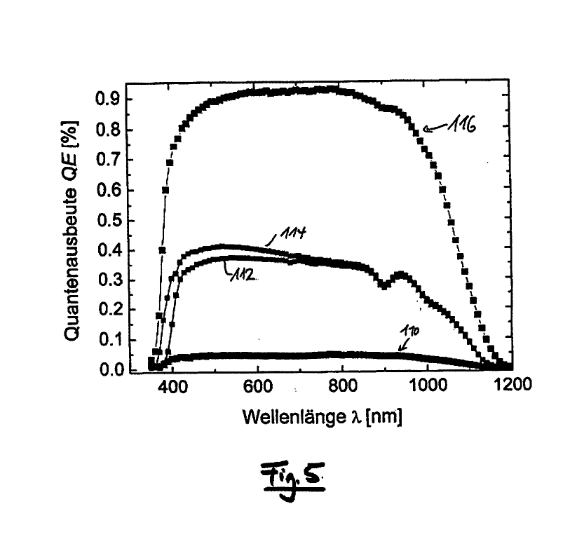

The diagram shown in FIG. 5 plots a quantum efficiency QE in percent above the wavelength λ of electromagnetic radiation, shown in nm. A first curve 110 shows the quantum efficiency for a conventional front contact, which is thus a photovoltaically inactive area, on a silicon solar cell of a solar cell module. A second curve 112 illustrates the quantum efficiency in the event that a white-coloured scattering element without electromagnetic shift has been applied to the front contact. A third curve 114, which comprises higher quantum efficiency values than the second curve 112, is obtained in the event that a fluorescent pigment, being a scattering element with electromagnetic shift in the ultraviolet range, is additionally applied onto the white-coloured scattering element without electromagnetic shift on the front contact. As a comparison, the fourth curve 116 shows the quantum efficiency for a photovoltaically active surface of the solar cell. For all measurements, the surfaces being irradiated were embedded in glass.

Assuming that a monocrystalline silicon solar cell has a total area of 240.48 cm² and the contact bands located on it occupy 9.6 cm², the short circuit [current density] JSC=1.7 mA/cm², calculated from the quantum efficiency, results in an efficiency rate of 14.64% for a conventional contact band containing silver.

The diagram in FIG. 5 shows that the short circuit current density for the scattering element without electromagnetic shift increases to a quantum efficiency of JSC=13.3 mA/cm² (second curve 112) and to JSC=14.3 mA/cm² (third curve 114) for an additionally applied fluorescent pigment, being a scattering element with electromagnetic shift. This results in a calculated efficiency increase of 14.84% and 14.86%, respectively. The larger the share of the surface or area in a solar cell module that has previously been unused photovoltaically, and therefore optically, the higher the increase in efficiency. Since the use of a luminescent material as a fluorescent pigment and thus as a scattering element with electromagnetic shift only improves the at least optical characteristics of a solar cell module, but does not affect the electrical properties, the increased number of photons results directly in a higher rate of efficiency. This effect also occurs in solar cell modules that are designed as thin-film modules.

The diagram in FIG. 5 uses quantum efficiency measurements to also show that the number of photons that generate power is increased in the blue wavelength range of the spectrum if an appropriate fluorescent pigment, being a scattering element with electromagnetic shift, is additionally applied to a scattering element without electromagnetic shift on contact bands of a monocrystalline silicon solar cell. The white-coloured scattering element without electromagnetic shift can also by itself direct enough photons onto the solar cell area in order to generate a significant amount of additional power. The incident light is shifted further into the blue light range of the spectrum in the case of the contact band of a monocrystalline silicon solar cell that is covered with a scattering element without electromagnetic shift and a fluorescent pigment in the form of a fluorescent paint coating, being thus a scattering element with electromagnetic shift.

1-10. (canceled)

11. A solar cell module, comprising:
a) a base with photovoltaically active areas and photovoltaically inactive areas, and in which at least one scattering element with or without electromagnetic shift is arranged above at least one photovoltaically inactive area of the base, the at least one photovoltaically inactive area being realized as a cell connection element and/or a contact finger element.

12. The solar cell module according to claim 11, wherein:
a) in which an additional scattering element is arranged above the at least one photovoltaically inactive area in addition to the at least one scattering element.

13. The solar cell module according to claim 12, wherein:
a) the at least one scattering element with electromagnetic shift is realized in the form of a fluorescent pigment and the at least one scattering element without electromagnetic shift is realized in the form of a Lambertian scatterer.

14. The solar cell module according to claim 11, wherein:
a) the at least one photovoltaically inactive area includes at least one at least optically and/or electrically inactive area.

15. The solar cell module according to claim 11, wherein:
a) the solar cell module is realized as a thin-film module and/or in which the at least one photovoltaically inactive area is realized as a space arranged next to at least one solar cell, and/or as a shadowed solar cell, which merely conducts power away.

16. The solar cell module according to claim 11, wherein:
a) the at least one scattering element with electromagnetic shift is designed to shift the spectrum of incident electromagnetic radiation, usually to absorb photons and to emit them with a different wavelength.

17. The solar cell module according to claim 12, wherein:
a) the at least one photovoltaically inactive area of the base and the at least one scattering element arranged above the photovoltaically inactive area are both embedded in an area of an optically transparent material.

18. The solar cell module according to claim 17, wherein:
a) a first transparent material consisting of plastic in which the at least one photovoltaically inactive area is embedded, and a second transparent material consisting of glass, arranged on the first transparent material, with the at least one scattering element being arranged in the area of at least one of the transparent materials.

19. A method for producing a solar cell module, wherein the solar cell module can be realized as a thin-film module and in which a base with photovoltaically active areas and photovoltaically inactive areas is provided for the solar cell module and in which at least one scattering element with or without electromagnetic shift is arranged above at least one photovoltaically inactive area of the base, the at least one photovoltaically inactive area being realized as a cell connection element and/or a contact finger element.

20. The method according to claim 19, wherein:
a) an additional scattering element is arranged on the at least one photovoltaically inactive area in addition to the at least one scattering element.

21. The solar cell module according to claim 11, wherein:
a) the at least one scattering element with electromagnetic shift is realized in the form of a fluorescent pigment and the at least one scattering element without electromagnetic shift is realized in the form of a Lambertian scatterer.
